(19) United States
(12) Patent Application Publication
(10) Pub. No.: US 2023/0409772 A1
(43) Pub. Date: Dec. 21, 2023

(54) OBJECT DISASSEMBLY OPTIMIZATION

(71) Applicant: International Business Machines Corporation, Armonk, NY (US)

(72) Inventors: Partho Ghosh, Kolkata (IN); Shailendra Moyal, Pune (IN); Sarbajit K. Rakshit, Pune (IN); Siddique M. Adoni, Bangalore (IN)

(21) Appl. No.: 17/807,764

(22) Filed: Jun. 20, 2022

(51) Int. Cl. G06F 30/20; G06Q 10/04

(52) U.S. Cl. CPC G06F 30/20; G06Q 10/04

(57) ABSTRACT

A processor may receive object data associated with an object. The processor may generate one or more simulations using object data. The one or more simulations may be associated with the object. The processor may identify one or more object components associated with the object. Identifying the one or more object components may be based, at least in part, on the one or more simulations. The processor may generate an optimized disassembly plan for the object based on the one or more object components. The optimized disassembly plan may include one or more disassembly stages. The processor may disassemble the object. The object may be disassembled using the optimized disassembling plan.

### BACKGROUND

Aspects of the present disclosure relate generally to the field of artificial intelligence, and more particularly to digital twin technology.

Digital twin technology may be used to generate virtual representations of physical objects. Using digital twin technology, one can determine how various stimuli may impact the physical object. For example, a digital twin of a building may be used to simulate how freezing temperatures (e.g., stimuli) may result in the building's waterpipes becoming frozen.

### SUMMARY

Embodiments of the present disclosure include a method, computer program product, and system for optimizing object disassembling.

A processor may receive object data associated with an object. The processor may generate one or more simulations using object data. The one or more simulations may be associated with the object. The processor may identify one or more object components associated with the object. Identifying the one or more object components may be based, at least in part, on the one or more simulations. The processor may generate an optimized disassembly plan for the object based on the one or more object components. The optimized disassembly plan may include one or more disassembly stages. The processor may disassemble the object. The object may be disassembled using the optimized disassembling plan.

The above summary is not intended to describe each illustrated embodiment or every implementation of the present disclosure.

### BRIEF DESCRIPTION OF THE DRAWINGS

The drawings included in the present disclosure are incorporated into, and form part of, the specification. They illustrate embodiments of the present disclosure and, along with the description, serve to explain the principles of the disclosure. The drawings are only illustrative of certain embodiments and do not limit the disclosure.

FIG. 1 illustrates a block diagram of an example object disassembling system, in accordance with aspects of the present disclosure.

FIG. 2 illustrates a flowchart of an example method for optimizing object disassembly, in accordance with aspects of the present disclosure.

FIG. 3A illustrates a cloud computing environment, in accordance with aspects of the present disclosure.

FIG. 3B illustrates abstraction model layers, in accordance with aspects of the present disclosure.

FIG. 4 illustrates a high-level block diagram of an example computer system that may be used in implementing one or more of the methods, tools, and modules, and any related functions, described herein, in accordance with aspects of the present disclosure.

While the embodiments described herein are amenable to various modifications and alternative forms, specifics thereof have been shown by way of example in the drawings and will be described in detail. It should be understood, however, that the particular embodiments described are not to be taken in a limiting sense. On the contrary, the intention is to cover all modifications, equivalents, and alternatives falling within the spirit and scope of the disclosure.

### DETAILED DESCRIPTION

Aspects of the present disclosure relate generally to the field of artificial intelligence, and, more particularly, to digital twin technology. While the present disclosure is not necessarily limited to such applications, various aspects of the disclosure may be appreciated through a discussion of various examples using this context.

Objects and structures surround us and are incorporated in our everyday lives. For various reasons these objects may need to be transported to other locations or removed because of age. As such there is a desire for a solution that allows for various objects to be disassembled in an efficient and productive manner with minimal impact on the environment surrounding the object of interest.

Before turning to the FIGs. it is noted that the benefits/novelties and intricacies of the proposed solution are that:

The object disassembling system may use digital twin technology to determine various aspects of an object. The digital twin technology may use information/data (e.g., object data) such as materials used to manufacture/construct the object, blueprints of the object, and geospatial criteria. The object disassembling system may be configured to determine (e.g., using digital twin simulation techniques) the health of the object (e.g., how much damage the object currently has) before the object disassembly is initiated. The object disassembling system may be configured to recommend one or more disassembly stages of the object (e.g., optimized disassembly plan) based on the health of the object. In some embodiments, the object disassembling system may be configured to consider the health of the object based on each of the one or more disassembly stages. In these embodiments, the object disassembling system may consider the health of the object to determine if the object is ready for the next disassembly stage of the one or more disassembly stages.

Based on the generated object's digital twin, the object disassembling system may use environment information and safety constraints (e.g., object data) to generate an optimized plan for object disassembly. The optimized disassembly plan may include a variety of disassembly stages (e.g., object stripping stage, electrical detachment stage, and introduction/removal of temporary supports and/or bracings). The optimized disassembly plan may include vertical disassembly, inclined disassembly, or bidirectional disassembly.

The object disassembling system may be configured to simulate and recommend an efficient method of disassembly (e.g., robotic disassembly, mechanical disassembly, manpower disassembly, or any combination thereof). The object disassembling system may dynamically augment the disassembly method or use a combination of disassembly methods.

The object disassembling system may be configured to simulate and determine the optimal sequence of the one or more disassembly stages of the optimized disassembly plan. In some embodiments, the object disassembling system may use a network of digital twins associated with the object and the environment surrounding the object.

The object disassembling system may be configured to analyze the environment (e.g., using object data) surrounding the object. The object disassembling system may analyze the environment's geospatial area, land infrastructure (e.g., underground pipelines, electrical networks, land contours or land slopes), and other structures associated with the environment not directly associated with the object (e.g., powerlines in the environment proximate to an object, such as a crane). The object disassembling system may simulate how each of the one or more disassembly stages may be impacted and generate one or more mitigation techniques that may be used to reduce or eliminate the impact of the one or more disassembly stages. For example, the object disassembling system may use digital twin simulation to predict the amount of dust produced during object disassembly (e.g., impact). The object disassembling system may recommend various dust capturing systems (e.g., mitigating techniques), such as, surface wetting procedures, electrostatically charged fog, atomized spray, or a hose based water sprinkler system that may be used during different disassembly stages.

The object disassembling system may consider the object's infrastructure while simulating the object's digital twin. The object disassembling system may simulate the disassembly of the object to determine if there is a potential for debris or fragmentation resulting from object disassembling. The object disassembling system may recommend appropriate safety boundary walls and where the safety boundary walls should be placed to mitigate the impact of debris and/or fragmentation resulting from disassembly.

The object disassembling system may generate an estimated cost associated with the optimized disassembly plan. The estimated cost may be based, at least in part, on the various simulations contemplated herein.

The object disassembling system may consider real-time object data (e.g., static and dynamic conditions associated with the object and surrounding environment) to simulate and/or determine object displacement, wind direction, vibrations resulting from object disassembly, pollution resulting from object disassembly, and how the object disassembly may impact the structures proximate to the object (e.g., those structures that may be impacted in some way by object disassembly). The object disassembly system may consider the aforementioned information/data to generate or alter the optimized disassembly plan.

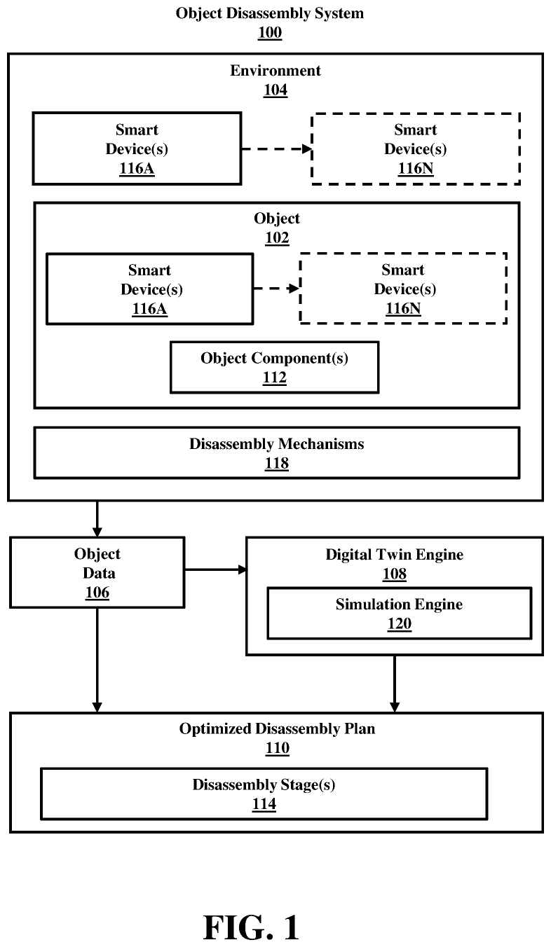

Referring now to FIG. 1, illustrated is a block diagram of an example object disassembly system 100 for optimizing object disassembly, in accordance with aspects of the present disclosure. FIG. 1 provides an illustration of only one implementation and does not imply any limitations with regard to the environments in which different embodiments may be implemented. Many modifications to the depicted environment may be made by those skilled in the art without departing from the scope of the invention as recited by the claims.

As depicted in FIG. 1, object disassembly system 100 may be configured to include object 102 in environment 104, object data 106, digital twin engine 108, and optimized disassembly plan 110. In embodiments, object 102 may include any object that may be broken down or disassembled into one or more object components. For example, object 102 may include, but is not limited to, a small robotic device, a large piece of machinery (e.g., a construction crane, wind turbine, etc.), a large building structure (e.g., bridge, barn, building, etc.) or any other structure contemplated herein. In some embodiments, object disassembly system 100 may be used to dismantle an object into more manageable pieces or object components 112.

In embodiments, reasons to dismantle object 102 may include, but are not limited to, transporting an object from one environment (e.g., environment 104) to another and breaking down an object for disposal. In one example, object 102 may be a wind turbine that is no longer functional and the various components of the wind turbine should be removed to a recycling facility. Object disassembly system 100 may be configured to provide an optimized disassembly plan 110 that may provide the most efficient object disassembly process (e.g., based on time requirements, transportability of each of the object components 112, cost of object disassembly process, and/or environmental conditions). In this example, object disassembly system 100 may generate an optimized disassembly plan 110 with one or more disassembly stages 114 that allows the wind turbine to be disassembled/dismantled into object components 112 (e.g., rotor, blades, tower, foundation, electrical components, etc.) that are easily transportable to the recycling center. In embodiments, environment 104 may refer to any space or area surrounding object 102 and/or associated with object 102. For example, environment 104 may refer to a room housing object 102, a manufacturing company (e.g., industrial floor) that manufactures various types of object 102, or an outdoor area (e.g., construction site) proximate (e.g., environment that may be impacted during disassembly of object 102) to object 102.

In embodiments, object disassembly system 100 may be configured to receive/collect object data 106 associated with object 102 and/or environment 104 (e.g., using one or more smart devices 116A-N). Object data may include, but is not limited to, information/data associated with: i) the design of object 102 (e.g., blueprints or generating design during actual object manufacturing/construction); ii) type of object; iii) object characteristics, such as object dimensions or size, object construction materials (e.g., fiberglass, wood, piping, circuitry, etc.), and weight/load distributions associated with the entire object 102 and/or the distribution associated with one or more object components; iv) number and type of object components 114; v) how object components 114 may be disassembled from object 102; vi) the environment 104, such as geospatial properties surrounding the object, such as ground stability (e.g., soil hardness, ground contours/slopes) and the proximity of other structures or items proximate to the other structures surrounding object 102 that may be affect disassembly and/or may be impacted by object disassembly; vii) damage detection associated with object 102 and/or environment 104; viii) various methods and/or tools that may be used to provide object disassembly (e.g., disassembly mechanisms 118); ix) information/data generated from various analyses and/or simulations contemplated herein (e.g., information/data generated by AI and machine learning analysis via digital twin engine 108/simulation engine 120); x) databases having information/data associated with disassembling/deconstruction of the same or similar objects; x) real-time information associated with the one or more object disassembly stages 114 of the optimized disassembly plan 110; xi) data associated with potential impacts/affects to object 102 and/or environment 104 during object disassembly; or any combination thereof.

In embodiments, object disassembly system 100 may be configured to store object data 106 collected over time in a historical repository. The historical repository may include any object data 106 contemplated herein. In embodiments, object disassembly system 100 may access the historical repository to generate one or more simulations using AI and machine learning capabilities (e.g., via digital twin engine 108 and/or simulation engine 120). The information used and generated from these analyses may be considered object data and may also be stored within the historical repository.

In embodiments, object disassembly system 100 may receive/collect object data 106 from one or more smart devices 116A-N. Smart devices 116A-N may include, but are not limited to devices such as, Internet of Things (IoT) devices, cameras, infrared sensors, ultrasounds, chemical sensors, wearable devices (e.g., device worn into the environment 104 by a user), or any combination thereof. In embodiments, object disassembly system 100 may configure one or more smart devices 116A-N to receive/collect object data 106 associated with environment 104 in real-time and/or to collect object data 106 over a particular time duration. Such object data 106 may be stored in a historical repository and accessed as needed by object disassembly system 100 by digital twin engine 108 and/or simulation engine 120 (e.g., when using AI and machine learning capabilities performing the various simulations/analyses contemplated herein). While some smart devices 116A-N may be configured within the environment 104, in some embodiments, other smart devices 116A-N may be further configured within or associated with object 102 and/or disassembly mechanism 118. For example, some smart devices 116A-N may be configured in environment 104 to collect object data 106 from environment 104 and object 102 and other smart devices 116A-N may be configured within object 102 to collect object data 106 directly from object 102. In some embodiments, some smart devices 116A-N may be configured within the apparatus performing one or more disassembling stages 114 of the optimized disassembling plans 110. For example, a robotic arm or crane configured to disassemble/dismantle a wind turbine according to optimized disassembly plan 110 may collect object data associated with each of the one or more object components 112 as they are removed from the wind turbine.

In embodiments, object disassembly system 100 may be configured to generate one or more simulations using object data 106. Object disassembly system 100 may be configured to generate the one or simulations using digital twin engine 108. Digital twin engine 108 may be enabled with AI and machine learning technology. In embodiments, digital twin engine 108 may generate one or more digital twins of object 102 and/or environment 104. These digital twins may be of object 102 and/or environment 104 prior to disassembly, during object disassembly, and after object disassembly. Object disassembly system 100 may use these digital twins to perform the one or more simulations and analyses contemplated herein. While in some embodiments, digital twin engine 108 may be configured to perform any and all analyses contemplated herein, in other embodiments, digital twin engine 110 may be configured to further include simulation engine 120 (e.g., enable with AI and machine learning technology). Simulation engine 120 may be configured to generate one or more simulations using the one or more digital twins generated by digital twin engine 108. In some embodiments, simulation engine 120 may replace digital twin engine 108 and be configured by object disassembly system 100 to perform any of the various analyses contemplated herein.

In embodiments, object disassembly system 100 may analyze (e.g., using digital twin engine 108/simulation engine 120) object data 106 to identify one or more object components 112 associated with object 102. Object components 112 may refer to the different pieces or elements that comprise object 102 that may be separated or detached from object 102 during disassembly. Object components 112 may include, but are not limited to, object systems (e.g., electrical systems, water systems, smart networks, etc.), fluids associated with the object (e.g., water associated with cooling the object during use, lubricant associated with maintaining various machinery components, or any other material, such as those that may be hazardous), and structures comprising object 102 (e.g., structural beams, external shell of the object, etc.). In embodiments, object disassembly system 100 may identify object components based on a desired size and/or weight of each object component. For example, in embodiments where a wind turbine is being recycled, object disassembly system 100 may consider the carrying capacity of each vehicle that will be responsible to transport each object component of the wind turbine to the recycling facility. In these embodiments, the object disassembly system 100 may ensure that the size and/or weight of each object component 112 may be configured within the available transport vehicles.

In embodiments, object disassembly system 100 may analyze (e.g., using digital twin engine 108 and/or simulation engine 120) to generate an optimized disassembly plan 110. Optimized disassembly plan 110 may refer to the optimal method of disassembling object 102 in environment 104. In embodiments, optimized disassembly plan 110 may include one or more disassembly stages 114. In these embodiments, each of the one or more disassembly stages 114 may include an operation contributing to the disassembly of object 102 (e.g., detachment or removal of an object component 112 from object 102). Examples of disassembly stages 114 include, but are not limited to, the removal of one or more object components 112, adding and/or removing object stabilizing means (e.g., supports or braces), initiating preventative protocols, issuing safety reports, and/or reanalyzing object 102 (e.g., using digital twin engine 108 and/or simulation engine 120).

Optimized disassembly system 100 may determine the optimized disassembly plan 110 should include one or more disassembly stages 114, associated with adding and/or removing object stabilizing means, by simulating one or more digital twins using digital twin engine 108. In an example embodiment where object 102 is a wind turbine, object disassembly system 100 may generate one or more simulations using the digital twins associated with the wind turbine and the surrounding environment. In this example embodiment, object disassembly system 100 may simulate the disassembly of the wind turbine and determine that after an initial disassembly stage (e.g., of the one or more disassembly stages 114) where a single blade is removed from the wind turbine, that the remaining wind turbines become unstable. As such, object disassembly system 100 may identify using the digital twin of the object what type of object stabilizing means should be used to create stability during object disassembly and when the object stabilizing means should be implemented and removed from object 102 and/or environment 104 (e.g., at which disassembly stage the object stabilizing means should be added to the object and when the object stabilizing means should be removed).

In some embodiments, optimized disassembly system 100 may base the optimized disassembly plan 110 on a level of damage of the object 102. In these embodiments, optimized disassembly system 100 simulate the one or more digital twins to determine if object 102 has any current damage that may impact disassembly of the object. For example, optimized disassembly system 100 may simulate, using object data, to determine if object 102 has a brittle object component 112 that may result in the object component 112 breaking during disassembly (e.g., resulting in a hazardous workspace). In these embodiments, optimized disassembly system 100 may identify (e.g., using object data 106) a level of damage associated with object disassembly (e.g., whether the object component 112 has a high or low likelihood of breaking during disassembly). Optimized disassembly system 100 may then compare the level of damage identified to a threshold level of damage (e.g., that may be determined by digital twin engine 108 or by an administrator). If the optimized disassembly system 100 determines that the level of damage does not exceed a threshold level, then optimized disassembly system 100 may then proceed with the optimized disassembly plan 110. In embodiments where the optimized disassembly system 100 determines that the level of damage exceeds a threshold level, then optimized disassembly system 100 may generate one or more recommendations. These one or more recommendations may include methods that may mitigate the level of damage to the object component 112 and ensure that object disassembly may be performed without object 102 incurring additional damage. For example, if optimized disassembly system 100 determines that an object component's brittleness (e.g., level of damage) exceeds a threshold, then during object disassembly, optimized disassembly plan 110 may include a disassembly stage where multiple robotic arms are used to detach or remove the object component to distribute the weight across the object component, in a manner that will reduce stress on the brittle object.

Optimized disassembly system 100 may determine the optimized disassembly plan 110 should include one or more disassembly stages 114 associated with initiating or discontinuing preventative protocols by simulating one or more digital twins using digital twin engine 108. In embodiments, optimized disassembly system 100 may use the one or more digital twins to simulate how environment 104 may be impacted by the object's disassembly. In such embodiments, optimized disassembly system 100 may analyze/simulate object data 106 associated with environment 104 surrounding object 102. Using these simulations (e.g., digital twins) optimized disassembly system 100 may identify one or more environment conditions that may arise as object 102 is disassembled. Optimized disassembly system 100 may then use the generated simulations to predict one or more impacts the environmental condition may have on environment 104 during object disassembly. Based on these predicted impacts, optimized disassembly system 100 may determine if one or more of the impacts are a hazardous impact. A hazardous impact may include an impact that negatively impacts environment 104. Examples of a hazardous impact may include, but are not limited to, pollutions (e.g., dust or leaking hazardous chemicals), vibrations, soil instability, etc. In these embodiments, optimized disassembly system 100 may recommend one or more hazard mitigation techniques (e.g., preventative protocols) that may reduce or eliminate the hazardous impact associated with the environmental condition caused during object disassembly (e.g., performing the one or more disassembly stages of optimized disassembly plan 110).

For example, in embodiments where the environmental condition is dust that may hazardously impact environment 104 (e.g., people, other structures etc.), optimized disassembly system 100 may have one or more disassembly stages that include one or more hazard mitigation techniques in place, such as dust capture systems (e.g., surface wetting protocols, electrostatically charged fog or atomized spray, water sprinkler systems, etc.). In these embodiments, the one or more disassembly stages may further include when and where the mitigation techniques should be performed in environment 104 during object 102 disassembly. In embodiments, that use electrostatic fog to mitigate the hazardous impact of dust on environment 104, the goal is to produce small water droplets with an opposite electrical charge from the airborne dust. This may result in greater attraction of the dust to the water droplets which can enhance particle control.

In embodiments, optimized disassembly system 100 may continuously receive object data 106 from one or more smart devices 116A as object 102 is being disassembled according to optimized disassembly plan 110. In these embodiments, optimized disassembly system 100 may perform contemporaneous simulations of one or more digital twins of object 102. Using these simulations, on or more impacts of the object's disassembly may be simulated. Optimized disassembly system 100 may identify an object impact from the one or more impacts. An object impact may include an impact to object 102 and/or environment 104 that may inhibit at least one disassembly stage of the one or more disassembly stages 114. An object impact may include, but is not limited, to soil disruptions that may result in the object being unstable, changes in weight distribution of the object 102, changes in the environment 104 surrounding object 102, etc. For example, a particular object component 112 may be removed that causes a change in weight distribution that results in the supporting soil of the object to shift. In these embodiments, optimized disassembly system 100 may generate (e.g., using digital twin engine 108/simulation engine 120) a new disassembly stage that may mitigate the object impact. For example, using the above example, optimized disassembly system 100 may determine that due to the changes in weight distribution that additional supports or the use of braces may prevent object 102 from having the change in weight distribution and ultimately eliminate the possibility of the soil shifting below the object. While in some embodiments, a new disassembly stage may be added to the optimized disassembly plan 110, in other embodiments, this new disassembly stage may replace at least one disassembly stage of the one or more disassembly stages 114, that is determined to affect the object (e.g., the object impact), with the new disassembly stage and dynamically updating the optimized disassembly plan with the new disassembly stage. In some embodiments, optimized disassembly system 100 may be configured to generate the overall cost that may be associated with the object 102's disassembly.

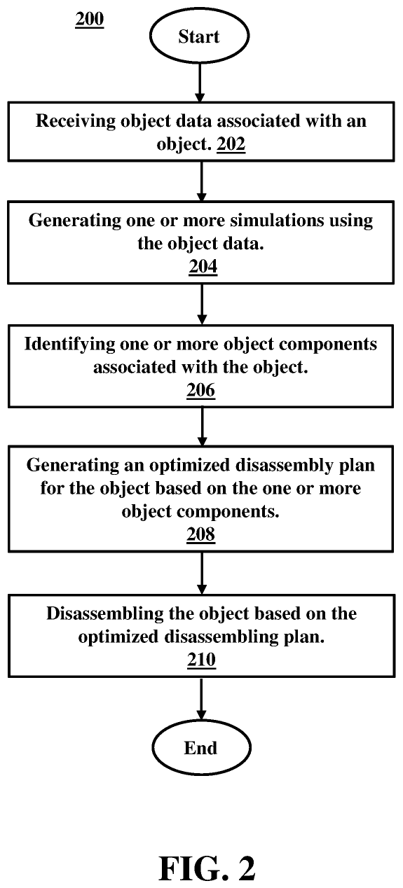

Referring now to FIG. 2, a flowchart illustrating an example method 200 for optimizing object disassembly, in accordance with embodiments of the present disclosure. FIG. 2 provides an illustration of only one implementation and does not imply any limitations with regard to the environments in which different embodiments may be implemented. Many modifications to the depicted environment may be made by those skilled in the art without departing from the scope of the invention as recited by the claims.

In some embodiments, the method 200 begins at operation 202 where a processor may receive object data associated with an object. In some embodiments, the method 200 proceeds to operation 204.

At operation 204, a processor may generate one or more simulations using the object data. In some embodiments, the one or more simulations are associated with the object. In some embodiments, the method 200 proceeds to operation 206.

At operation 206, a processor may identify one or more object components associated with the object. In some embodiments, the processor may identify one or more object components based, at least in part, on the one or more simulations. In some embodiments, the method 200 may proceed to operation 208.

At operation 208, a processor may generate an optimized disassembly plan for the object based on the one or more object components. In some embodiments, the optimized disassembly plan may include one or more disassembly stages. In some embodiments, the method 200 may proceed to operation 210.

At operation 210, the processor may disassemble the object using the optimized disassembling plan. In some embodiments, as depicted in FIG. 2, after operation 208, the method 200 may end.

In some embodiments, discussed below there are one or more operations of the method 200 not depicted for the sake of brevity and which are discussed throughout this disclosure. Accordingly, in some embodiments, the processor may base the one or more simulations on one or more digital twins of the object.

In some embodiments, the processor may identify a level of damage associated with the object based, at least in part, on the one or more simulations. In these embodiments, the processor may determine the level of damage exceeds a threshold level. The processor ma y then generate one or more recommendations, wherein the one or more actions are based on the level of damage exceeding the threshold level. In some embodiments, the processor may analyze object data associated with the environment surrounding the object. The processor may identify an environmental condition associated with disassembling the object. The processor may then predict one or more impacts of the environmental condition on the environment.

In some embodiments, the processor may identify a hazardous impact from the one or more impacts of the environmental condition. In these embodiments, the processor may recommend one or more hazard mitigation techniques associated with the hazardous impact.

In some embodiments, the processor may simulate object data in real-time associated with disassembling the object. In these embodiments, the processor may predict one or more impacts associated with disassembling the object. The processor may then identify an object impact from one or more impacts. The object impact may inhibit at least one disassembly stage of the one or more disassembly stages of the optimized disassembly plan. In these embodiments, the processor may generate a new disassembly stage. The processor may replace the at least one disassembly stage of the one or more disassembly stages inhibited by the object impact with the new disassembly stage. The processor may then dynamically update the optimized disassembly plan with the new disassembly stage.

It is to be understood that although this disclosure includes a detailed description on cloud computing, implementation of the teachings recited herein are not limited to a cloud computing environment. Rather, embodiments of the present disclosure are capable of being implemented in conjunction with any other type of computing environment now known or later developed.

Cloud computing is a model of service delivery for enabling convenient, on-demand network access to a shared pool of configurable computing resources (e.g., networks, network bandwidth, servers, processing, memory, storage, applications, virtual machines, and services) that can be rapidly provisioned and released with minimal management effort or interaction with a provider of the service. This cloud model may include at least five characteristics, at least three service models, and at least four deployment models.

Characteristics are as follows:

On-demand self-service: a cloud consumer can unilaterally provision computing capabilities, such as server time and network storage, as needed automatically without requiring human interaction with the service's provider.

Broad network access: capabilities are available over a network and accessed through standard mechanisms that promote use by heterogeneous thin or thick client platforms (e.g., mobile phones, laptops, and PDAs).

Resource pooling: the provider's computing resources are pooled to serve multiple consumers using a multi-tenant model, with different physical and virtual resources dynamically assigned and reassigned according to demand. There is a sense of portion independence in that the consumer generally has no control or knowledge over the exact portion of the provided resources but may be able to specify portion at a higher level of abstraction (e.g., country, state, or datacenter).

Rapid elasticity: capabilities can be rapidly and elastically provisioned, in some cases automatically, to quickly scale out and rapidly released to quickly scale in. To the consumer, the capabilities available for provisioning often appear to be unlimited and can be purchased in any quantity at any time.

Measured service: cloud systems automatically control and optimize resource use by leveraging a metering capability at some level of abstraction appropriate to the type of service (e.g., storage, processing, bandwidth, and active user accounts). Resource usage can be monitored, controlled, and reported, providing transparency for both the provider and consumer of the utilized service.

Service Models are as follows:

Software as a Service (SaaS): the capability provided to the consumer is to use the provider's applications running on a cloud infrastructure. The applications are accessible from various client devices through a thin client interface such as a web browser (e.g., web-based e-mail). The consumer does not manage or control the underlying cloud infrastructure including network, servers, operating systems, storage, or even individual application capabilities, with the possible exception of limited user-specific application configuration settings.

Platform as a Service (PaaS): the capability provided to the consumer is to deploy onto the cloud infrastructure consumer-created or acquired applications created using programming languages and tools supported by the provider. The consumer does not manage or control the underlying cloud infrastructure including networks, servers, operating systems, or storage, but has control over the deployed applications and possibly application hosting environment configurations.

Infrastructure as a Service (IaaS): the capability provided to the consumer is to provision processing, storage, networks, and other fundamental computing resources where the consumer is able to deploy and run arbitrary software, which can include operating systems and applications. The consumer does not manage or control the underlying cloud infrastructure but has control over operating systems, storage, deployed applications, and possibly limited control of select networking components (e.g., host firewalls).

Deployment Models are as follows:

Private cloud: the cloud infrastructure is operated solely for an organization. It may be managed by the organization or a third party and may exist on-premises or off-premises.

Community cloud: the cloud infrastructure is shared by several organizations and supports a specific community that has shared concerns (e.g., mission, security requirements, policy, and compliance considerations). It may be managed by the organizations or a third party and may exist on-premises or off-premises.

Public cloud: the cloud infrastructure is made available to the general public or a large industry group and is owned by an organization selling cloud services.

Hybrid cloud: the cloud infrastructure is a composition of two or more clouds (private, community, or public) that remain unique entities but are bound together by standardized or proprietary technology that enables data and application portability (e.g., cloud bursting for load-balancing between clouds).

A cloud computing environment is service oriented with a focus on statelessness, low coupling, modularity, and semantic interoperability. At the heart of cloud computing is an infrastructure that includes a network of interconnected nodes.

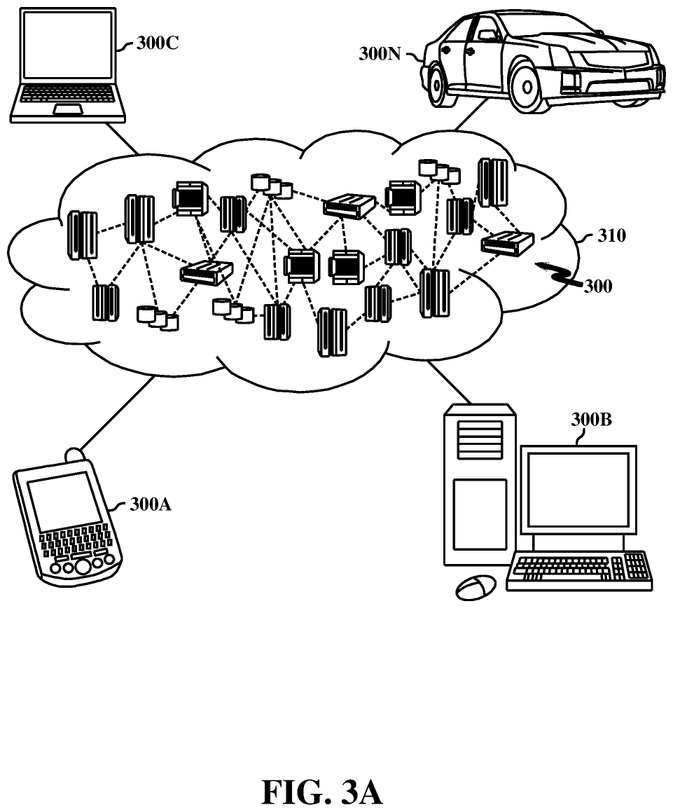

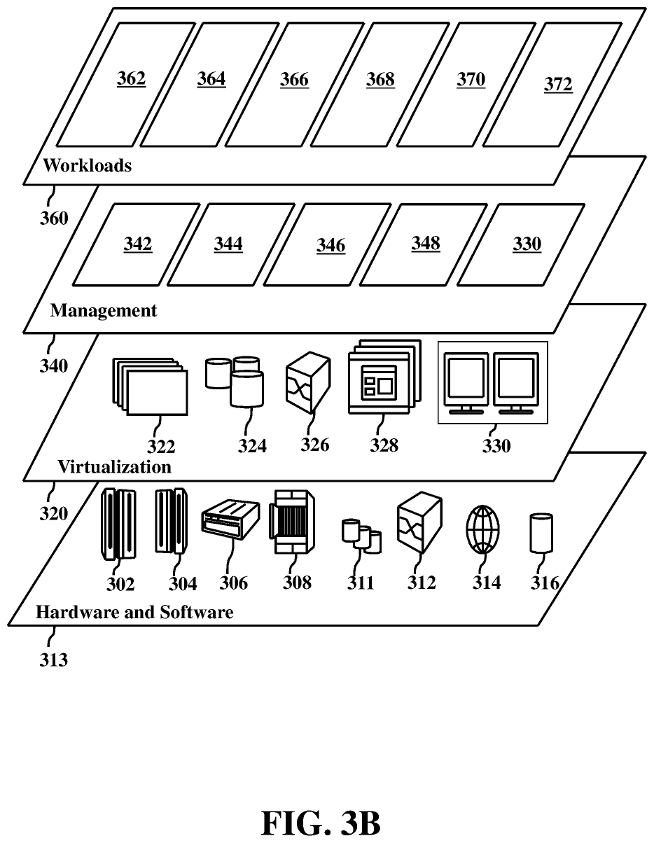

FIG. 3A, illustrated is a cloud computing environment 310 is depicted. As shown, cloud computing environment 310 includes one or more cloud computing nodes 300 with which local computing devices used by cloud consumers, such as, for example, personal digital assistant (PDA) or cellular telephone 300A, desktop computer 300B, laptop computer 300C, and/or automobile computer system 300N may communicate. Nodes 300 may communicate with one another. They may be grouped (not shown) physically or virtually, in one or more networks, such as Private, Community, Public, or Hybrid clouds as described hereinabove, or a combination thereof.

This allows cloud computing environment 310 to offer infrastructure, platforms and/or software as services for which a cloud consumer does not need to maintain resources on a local computing device. It is understood that the types of computing devices 300A-N shown in FIG. 3A are intended to be illustrative only and that computing nodes 300 and cloud computing environment 310 can communicate with any type of computerized device over any type of network and/or network addressable connection (e.g., using a web browser).

FIG. 3B, illustrated is a set of functional abstraction layers provided by cloud computing environment 310 (FIG. 3A) is shown. It should be understood in advance that the components, layers, and functions shown in FIG. 3B are intended to be illustrative only and embodiments of the disclosure are not limited thereto. As depicted below, the following layers and corresponding functions are provided.

Hardware and software layer 315 includes hardware and software components. Examples of hardware components include: mainframes 302; RISC (Reduced Instruction Set Computer) architecture based servers 304; servers 306; blade servers 308; storage devices 311; and networks and networking components 312. In some embodiments, software components include network application server software 314 and database software 316.

Virtualization layer 320 provides an abstraction layer from which the following examples of virtual entities may be provided: virtual servers 322; virtual storage 324; virtual networks 326, including virtual private networks; virtual applications and operating systems 328; and virtual clients 330.

In one example, management layer 340 may provide the functions described below. Resource provisioning 342 provides dynamic procurement of computing resources and other resources that are utilized to perform tasks within the cloud computing environment. Metering and Pricing 344 provide cost tracking as resources are utilized within the cloud computing environment, and billing or invoicing for consumption of these resources. In one example, these resources may include application software licenses. Security provides identity verification for cloud consumers and tasks, as well as protection for data and other resources. User portal 346 provides access to the cloud computing environment for consumers and system administrators. Service level management 348 provides cloud computing resource allocation and management such that required service levels are met. Service Level Agreement (SLA) planning and fulfillment 350 provide pre-arrangement for, and procurement of, cloud computing resources for which a future requirement is anticipated in accordance with an SLA.

Workloads layer 360 provides examples of functionality for which the cloud computing environment may be utilized. Examples of workloads and functions which may be provided from this layer include: mapping and navigation 362; software development and lifecycle management 364; virtual classroom education delivery 366; data analytics processing 368; transaction processing 370; and object disassembling 372.

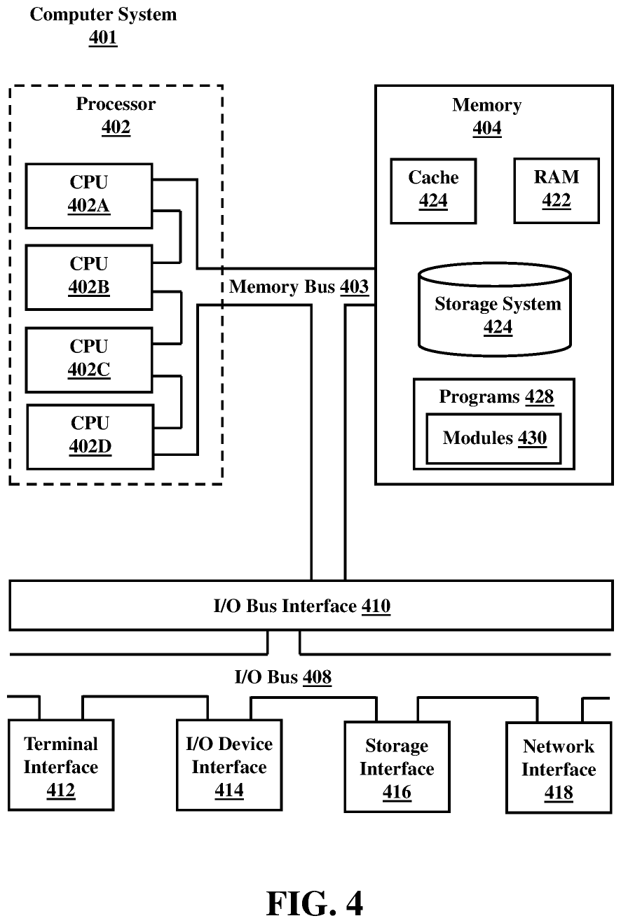

FIG. 4, illustrated is a high-level block diagram of an example computer system 401 that may be used in implementing one or more of the methods, tools, and modules, and any related functions, described herein (e.g., using one or more processor circuits or computer processors of the computer), in accordance with embodiments of the present disclosure. In some embodiments, the major components of the computer system 401 may comprise one or more CPUs 402, a memory subsystem 404, a terminal interface 412, a storage interface 416, an I/O (Input/Output) device interface 414, and a network interface 418, all of which may be communicatively coupled, directly or indirectly, for inter-component communication via a memory bus 403, an I/O bus 408, and an I/O bus interface unit 410.

The computer system 401 may contain one or more general-purpose programmable central processing units (CPUs) 402A, 402B, 402C, and 402D, herein generically referred to as the CPU 402. In some embodiments, the computer system 401 may contain multiple processors typical of a relatively large system; however, in other embodiments the computer system 401 may alternatively be a single CPU system. Each CPU 402 may execute instructions stored in the memory subsystem 404 and may include one or more levels of on-board cache.

System memory 404 may include computer system readable media in the form of volatile memory, such as random access memory (RAM) 422 or cache memory 424. Computer system 401 may further include other removable/non-removable, volatile/non-volatile computer system storage media. By way of example only, storage system 426 can be provided for reading from and writing to a non-removable, non-volatile magnetic media, such as a “hard drive.” Although not shown, a magnetic disk drive for reading from and writing to a removable, non-volatile magnetic disk (e.g., a “floppy disk”), or an optical disk drive for reading from or writing to a removable, non-volatile optical disc such as a CD-ROM, DVD-ROM or other optical media can be provided. In addition, memory 404 can include flash memory, e.g., a flash memory stick drive or a flash drive. Memory devices can be connected to memory bus 403 by one or more data media interfaces. The memory 404 may include at least one program product having a set (e.g., at least one) of program modules that are configured to carry out the functions of various embodiments.

One or more programs/utilities 428, each having at least one set of program modules 430 may be stored in memory 404. The programs/utilities 428 may include a hypervisor (also referred to as a virtual machine monitor), one or more operating systems, one or more application programs, other program modules, and program data. Each of the operating systems, one or more application programs, other program modules, and program data or some combination thereof, may include an implementation of a networking environment. Programs 428 and/or program modules 430 generally perform the functions or methodologies of various embodiments.

Although the memory bus 403 is shown in FIG. 4 as a single bus structure providing a direct communication path among the CPUs 402, the memory subsystem 404, and the I/O bus interface 410, the memory bus 403 may, in some embodiments, include multiple different buses or communication paths, which may be arranged in any of various forms, such as point-to-point links in hierarchical, star or web configurations, multiple hierarchical buses, parallel and redundant paths, or any other appropriate type of configuration. Furthermore, while the I/O bus interface 410 and the I/O bus 408 are shown as single respective units, the computer system 401 may, in some embodiments, contain multiple I/O bus interface units 410, multiple I/O buses 408, or both. Further, while multiple I/O interface units are shown, which separate the I/O bus 408 from various communications paths running to the various I/O devices, in other embodiments some or all of the I/O devices may be connected directly to one or more system I/O buses.

In some embodiments, the computer system 401 may be a multi-user mainframe computer system, a single-user system, or a server computer or similar device that has little or no direct user interface, but receives requests from other computer systems (clients). Further, in some embodiments, the computer system 401 may be implemented as a desktop computer, portable computer, laptop or notebook computer, tablet computer, pocket computer, telephone, smartphone, network switches or routers, or any other appropriate type of electronic device.

It is noted that FIG. 4 is intended to depict the representative major components of an exemplary computer system 401. In some embodiments, however, individual components may have greater or lesser complexity than as represented in FIG. 4, components other than or in addition to those shown in FIG. 4 may be present, and the number, type, and configuration of such components may vary.

As discussed in more detail herein, it is contemplated that some or all of the operations of some of the embodiments of methods described herein may be performed in alternative orders or may not be performed at all; furthermore, multiple operations may occur at the same time or as an internal part of a larger process.

The present disclosure may be a system, a method, and/or a computer program product at any possible technical detail level of integration. The computer program product may include a computer readable storage medium (or media) having computer readable program instructions thereon for causing a processor to carry out aspects of the present disclosure.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present disclosure may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Although the present disclosure has been described in terms of specific embodiments, it is anticipated that alterations and modification thereof will become apparent to the skilled in the art. Therefore, it is intended that the following claims be interpreted as covering all such alterations and modifications as fall within the true spirit and scope of the disclosure.

What is claimed is:

1. A computer-implemented method for optimizing disassembly of an object, the method comprising:
receiving, by a processor, object data associated with an object;
generating one or more simulations using the object data, wherein the one or more simulations are representations of the object;
identifying one or more object components associated with the object, wherein identifying the one or more object components are based, at least in part, on the one or more simulations;
generating an optimized disassembly plan for the object based on the one or more object components, wherein the optimized disassembly plan includes one or more disassembly stages; and
disassembling the object, wherein the object is disassembled using the optimized disassembling plan.

2. The method of claim 1, wherein the one or more simulations are based, at least in part, on one or more digital twins of the object.

3. The method of claim 1, further comprising:
identifying a level of damage associated with the object based, at least in part, on the one or more simulations;
determining the level of damage exceeds a threshold level; and
generating one or more recommendations, wherein the one or more recommendations are based on the level of damage exceeding the threshold level.

4. The method of claim 1, further comprising:
analyzing object data associated with an environment, wherein the environment surrounds the object;
identifying an environmental condition associated with disassembling the object; and
predicting one or more impacts of the environmental condition on the environment.

5. The method of claim 4, including:
identifying a hazardous impact from the one or more impacts of the environmental condition; and
recommending one or more hazard mitigation techniques associated with the hazardous impact.

6. The method of claim 1, including:
simulating object data in real-time associated with disassembling the object;
predicting one or more impacts associated with disassembling the object; and
identifying an object impact from one or more impacts, wherein the object impact inhibits at least one disassembly stage of the one or more disassembly stages of the optimized disassembly plan.

7. The method of claim 6, further comprising:
generating a new disassembly stage;
replacing the at least one disassembly stage of the one or more disassembly stages inhibited by the object impact with the new disassembly stage; and
dynamically updating the optimized disassembly plan with the new disassembly stage.

8. A system for optimizing the disassembly of an object, the system comprising:
a memory; and
a processor in communication with the memory, the processor being configured to perform operations comprising:
receiving object data associated with an object;
generating one or more simulations using the object data, wherein the one or more simulations are representations of the object;
identifying one or more object components associated with the object, wherein identifying the one or more object components are based, at least in part, on the one or more simulations;
generating an optimized disassembly plan for the object based on the one or more object components, wherein the optimized disassembly plan includes one or more disassembly stages; and
disassembling the object, wherein the object is disassembled using the optimized disassembling plan.

9. The system of claim 8, wherein the one or more simulations are based, at least in part, on one or more digital twins of the object.

10. The system of claim 8, further comprising:
identifying a level of damage associated with the object based, at least in part, on the one or more simulations;
determining the level of damage exceeds a threshold level; and
generating one or more recommendations, wherein the one or more recommendations are based on the level of damage exceeding the threshold level.

11. The system of claim 8, further comprising:
analyzing object data associated with an environment, wherein the environment surrounds the object;
identifying an environmental condition associated with disassembling the object; and
predicting one or more impacts of the environmental condition on the environment.

12. The system of claim 11, including:
identifying a hazardous impact from the one or more impacts of the environmental condition; and
recommending one or more hazard mitigation techniques associated with the hazardous impact.

13. The system of claim 8, including:
simulating object data in real-time associated with disassembling the object;
predicting one or more impacts associated with disassembling the object; and
identifying an object impact from one or more impacts, wherein the object impact inhibits at least one disassembly stage of the one or more disassembly stages of the optimized disassembly plan.

14. The system of claim 13, further comprising:
generating a new disassembly stage;
replacing the at least one disassembly stage of the one or more disassembly stages inhibited by the object impact with the new disassembly stage; and
dynamically updating the optimized disassembly plan with the new disassembly stage.

15. A computer program product for optimizing the disassembly of an object, the computer program product comprising a computer readable storage medium having program instructions embodied therewith, the program instructions executable by a processor to cause the processors to perform a function, the function comprising:
receiving object data associated with an object;
generating one or more simulations using the object data, wherein the one or more simulations are representations of the object;
identifying one or more object components associated with the object, wherein identifying the one or more object components are based, at least in part, on the one or more simulations;
generating an optimized disassembly plan for the object based on the one or more object components, wherein the optimized disassembly plan includes one or more disassembly stages; and
disassembling the object, wherein the object is disassembled using the optimized disassembling plan.

16. The computer program product of claim 15, further comprising:
identifying a level of damage associated with the object based, at least in part, on the one or more simulations;
determining the level of damage exceeds a threshold level; and
generating one or more recommendations, wherein the one or more recommendations are based on the level of damage exceeding the threshold level.

17. The computer program product of claim 15, further comprising:
analyzing object data associated with an environment, wherein the environment surrounds the object;
identifying an environmental condition associated with disassembling the object; and
predicting one or more impacts of the environmental condition on the environment.

18. The computer program product of claim 17, including:
identifying a hazardous impact from the one or more impacts of the environmental condition; and
recommending one or more hazard mitigation techniques associated with the hazardous impact.

19. The computer program product of claim 15, including:
simulating object data in real-time associated with disassembling the object;
predicting one or more impacts associated with disassembling the object; and
identifying an object impact from one or more impacts, wherein the object impact inhibits at least one disassembly stage of the one or more disassembly stages of the optimized disassembly plan.

20. The computer program product of claim 19, further comprising:
generating a new disassembly stage;
replacing the at least one disassembly stage of the one or more disassembly stages inhibited by the object impact with the new disassembly stage; and
dynamically updating the optimized disassembly plan with the new disassembly stage.
